(19) United States
(12) Patent Application Publication
(10) Pub. No.: US 2003/0112080 A1
(43) Pub. Date: Jun. 19, 2003

(54) Temperature compensation device and electronic apparatus comprising such a device

(76) Inventors: Sebastien Amiot, St. Aubin S/Mer (FR); Bertrand Duloy, Villons-Les-Buissons (FR)

Correspondence Address: PHILIPS ELECTRONICS NORTH AMERICAN CORP, 580 WHITE PLAINS RD, TARRYTOWN, NY, 10591, US

(21) Appl. No.: 10/313,798

(22) Filed: Dec. 6, 2002

(30) Foreign Application Priority Data
Dec. 11, 2001 (FR) 0115977

(51) Int. Cl. H03L 7/00

(52) U.S. Cl. 331/36 C

(57) ABSTRACT

The invention relates to an electronic apparatus comprising at least one transistor having a control terminal and an intrinsic capacitance junction with a variable value as a function of the temperature, said transistor being associated with a compensation device for compensating the effects of the variation of said intrinsic capacitance junction. To this end, the electronic apparatus is characterized in that said compensation device comprises a combination of means behaving as a variable capacitance, said variable capacitance having such a variation as a function of the temperature that it compensates said effects, said variable capacitance being connected to said intrinsic capacitance.

The invention is particularly advantageous for compensating the frequency drift of a voltage-controlled oscillator.

### FIELD OF THE INVENTION

The invention relates to an electronic apparatus comprising at least one transistor having a control terminal and an intrinsic capacitance junction with a variable value as a function of the temperature, said transistor being associated with a compensation device for compensating the effects of the variation of said intrinsic capacitance junction.

The invention notably finds numerous applications in electronic apparatuses comprising resonant circuits.

### BACKGROUND OF THE INVENTION

It is known from the prior art that transistors have several intrinsic capacitance junctions with a variable value as a function of the temperature. Particularly, one of the intrinsic capacitances is connected between the input terminal (referred to as base in a bipolar transistor and as gate in a field effect transistor) and an output terminal of the transistor (referred to as collector in a bipolar transistor and as drain in a field effect transistor). Due to the Miller effect, this intrinsic capacitance has its value amplified by the gain of the transistor and thus becomes preponderant with respect to the other intrinsic capacitances. This intrinsic capacitance increases with the temperature.

Although it has a low value, this intrinsic capacitance turns out to be detrimental for the operating stability of electronic apparatuses when the temperature develops, particularly in electronic apparatuses comprising resonant circuits. Indeed, to the extent where a resonant circuit generally comprises the parallel arrangement of an inductance and a capacitance, referred to as extrinsic capacitance, and the resonant circuit is associated with transistors, the capacitive effect of the intrinsic capacitance will cumulate due to the coupling to the extrinsic capacitance. This causes a variation of the frequency of the signal generated by the resonant circuit when the temperature varies, which involves a frequency drift of the resonant circuit and perturbs the operation of the electronic apparatus.

U.S. Pat. No. 6,043,720 describes an electronic circuit associated with a compensation device and comprising amplifying transistors whose intrinsic capacitance junction varies as a function of the temperature. Means for generating a bias signal having a level varying as a function of the temperature are provided, which bias signal modifies the bias of the electronic circuit for compensating the effects of the variation of the intrinsic capacitance of said transistors. Additional resistances having a positive and a negative temperature coefficient are also provided.

These compensation means have a certain number of limitations.

Indeed, in so far as the means used in the prior-art document consist of a direct modification of the bias parameters of the oscillator, this solution presents the risk that the oscillation conditions of the oscillator are no longer respected, leading to instabilities of operation of the oscillator, or even to its stopping.

On the other hand, the means used require a difficult regulation of the compensation parameters to the extent that a large number of components is implemented. This regulation of the parameters is extra guaranteed for only a given oscillator because the same component may have slight characteristics. This implies that a regulation of the bias parameters must be made for each oscillator.

Moreover, due to the high number of components used, the solution is costly and difficult to integrate in an integrated circuit.

### OBJECT AND SUMMARY OF THE INVENTION

It is an object of the invention to provide an electronic apparatus comprising an improved compensation device for compensating the variation of the intrinsic capacitance of transistors used in said electronic apparatus.

To this end, the compensation device is characterized in that it comprises a combination of means behaving as a variable capacitance, said variable capacitance having such a variation as a function of the temperature that it compensates said effects, said variable capacitance being connected to said intrinsic capacitance.

The variable capacitance is such that its variation compensates the effects of the intrinsic capacitance variation on the operation of the electronic apparatus by cumulation of the capacitive effects of the variable capacitance and the intrinsic capacitance.

The advantage of such a solution is that it acts directly on the intrinsic capacitance and not indirectly as in the prior-art document, by acting on the bias parameters of the electronic apparatus. Indeed, the compensation device according to the invention does not act on the bias of the components constituting the electronic apparatus. This gives the invention a great flexibility of use to the extent that the compensation device may be easily inserted in an electronic apparatus without modifying the bias parameters. The proposed solution thus prevents any perturbation of the stability of operation of said electronic apparatus, which would be caused by a modification of the bias parameters.

The invention is also characterized in that the combination of means comprises:

means for generating a bias signal of a variable level as a function of the temperature,

a junction which is reverse-biased by said bias signal, said reverse-biased junction being connected to said control terminal.

Said combination of means constitutes an economic solution because it requires a small number of components.

The invention advantageously benefits from the characteristics of a reverse-biased junction and particularly of presenting a given capacitance for a given bias signal. The association of the generating means with the diode thus behaves as a variable capacitance when the temperature varies.

The use of a single junction is in itself advantageous because it does not need a diode of the varicap type, which is an expensive component.

This solution is also advantageous because the connection of the compensation device with the transistor (whose intrinsic capacitance must be modified) is easy because it consists of a single connection of the reverse-biased junction with said transistor.

The invention is also characterized in that the generating means comprise:

a set of junctions arranged in series for generating a current of a variable value as a function of the temperature,

a current mirror of said variable current for generating said bias signal.

Such generating means allow generation of a bias signal whose amplitude varies in a monotonous manner when the temperature varies. These generating means are components which are currently used in the electronic industry, which leads to an economic solution.

The invention also relates to a compensation device having the characteristic features described above.

The invention also relates to an integrated circuit comprising at least a compensation device having the characteristic features described above.

The invention particularly relates to an electronic apparatus of the tuner type for receiving a RF signal, said tuner comprising at least a compensation device having the characteristic features described above.

A tuner generally comprises several selective filters for selecting a given channel in a RF input signal and at least an oscillator generating a signal to a mixer for effecting a frequency shift of said channel. In contrast to the filters, the oscillator generally comprises active components of the transistor type for generating a negative conductance with the object of maintaining the oscillations. The frequencies of the selective filters and of the oscillator are adjusted by means of a unique variable control voltage generated by a phase-locked loop (hereinafter denoted by PLL) with which the frequency of the signal generated by the oscillator can be stabilized.

Said active components of the transistor type have an intrinsic capacitance which varies with the temperature. To prevent this intrinsic capacitance variation from entailing a change of the frequency of the signal generated by the oscillator, the control voltage generated by the PLL is modified.

In so far as this control voltage is unique, the modified control voltage is also applied to the different filters, with the consequence that the nominal filtering frequency for the channel shifts. This shift is detrimental not only because it involves a loss of selectivity of the filters but also an inhomogeneous frequency attenuation on the width of the channel of the signals thus filtered.

The use of a compensation device according to the invention in a tuner is particularly advantageous because it allows compensation of the variation of the intrinsic capacitances of said transistors without the control voltage being modified. As the oscillator is thus internally compensated, it avoids the shift of the filters, which leads to a better linearity of operation of the tuner when the temperature varies.

The invention also relates to a television signal receiver comprising a tuner provided with at least a compensation device having the characteristic features described above.

### BRIEF DESCRIPTION OF THE DRAWINGS

These and other aspects of the invention are apparent from and will be elucidated, by way of non-limitative example, with reference to the embodiment(s) described hereinafter.

In the drawings:

FIG. 1 illustrates the principle of operation of the compensation device according to the invention,

FIG. 2 shows an embodiment of a circuit with which a bias signal varying as a function of the temperature can be supplied,

FIG. 3 illustrates an example of the variation of the bias signal as a function of the temperature,

FIG. 4 illustrates an example of the variation of the variable capacitance according to the invention as a function of the temperature,

FIG. 5 is a simplified diagram of an oscillator associated with a compensation device according to the invention,

FIG. 6 is a detailed diagram of a circuit associated with a compensation device according to the invention,

FIG. 7 shows a tuner comprising an oscillator associated with a compensation device according to the invention,

FIG. 8 shows a television signal receiver comprising a tuner provided with a compensation device according to the invention.

### DESCRIPTION OF EMBODIMENTS

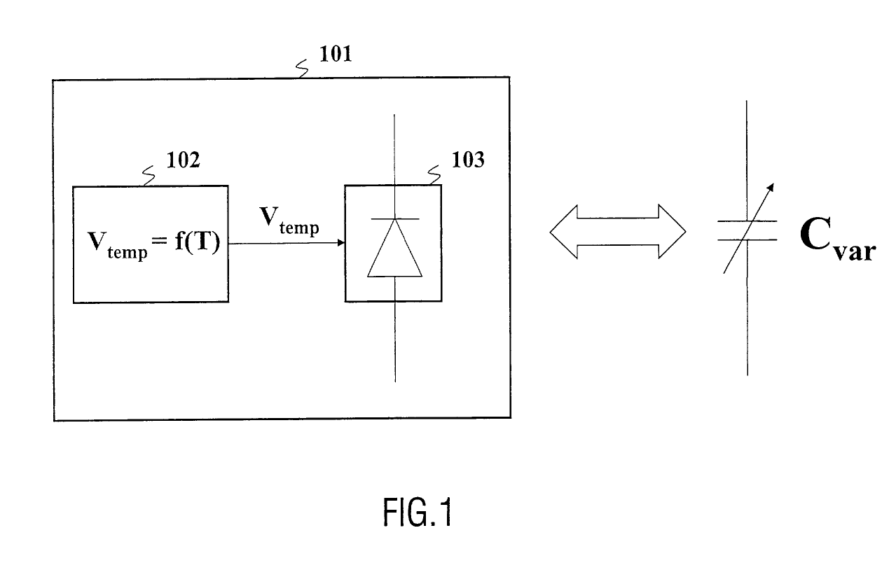

FIG. 1 illustrates the principle of operation of the compensation device 101 according to the invention.

The compensation device 101 according to the invention comprises means 102 for generating a bias signal Vₜₑₘₚ, and a junction 103 which is reverse-biased by said bias signal. The bias signal Vₜₑₘₚ has the characteristic feature of having a variable level when the temperature T varies. The association of the means 102 and 103 is equivalent to a capacitance Cᵥₐᵣ having a variable value as a function of the temperature.

When this capacitance Cᵥₐᵣ is connected to a transistor having an intrinsic capacitance with a variable value as a function of the temperature, it compensates the effect of said intrinsic capacitance.

The junction 103 may particularly correspond to a diode, for example, a diode of the Schottky type or to a transistor junction.

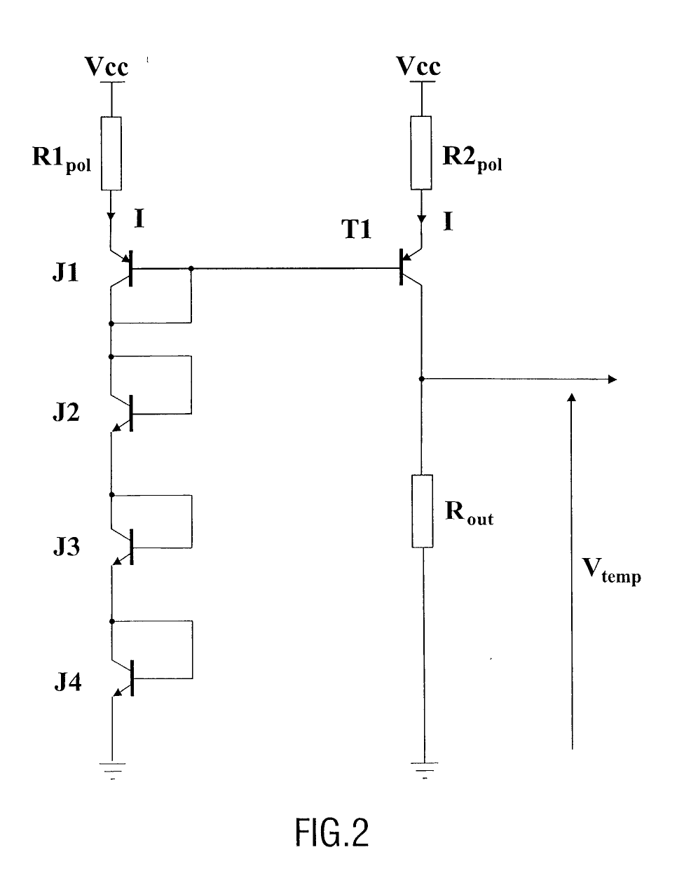

FIG. 2 shows an embodiment of a circuit with which a bias signal Vₜₑₘₚ varying as a function of the temperature T can be supplied.

This circuit comprises a group of series-arranged junctions J1-J2-J3-J4 for generating a current I having a variable value as a function of the temperature. These junctions are constituted in this case by transistors in which the base-collector junctions are short-circuited. The resistances R1ₚₒₗ and R2ₚₒₗ of an identical value have the role of biasing the different elements. In association with the junction J1 having characteristics which are similar to the junction of the transistor T1, the transistor T1 constitutes a current mirror. The emitter current of the transistor T1 is then equal to the current I. The resistance Rₒᵤₜ allows generation of the bias signal Vₜₑₘₚ at its terminals when it is traversed by the current I.

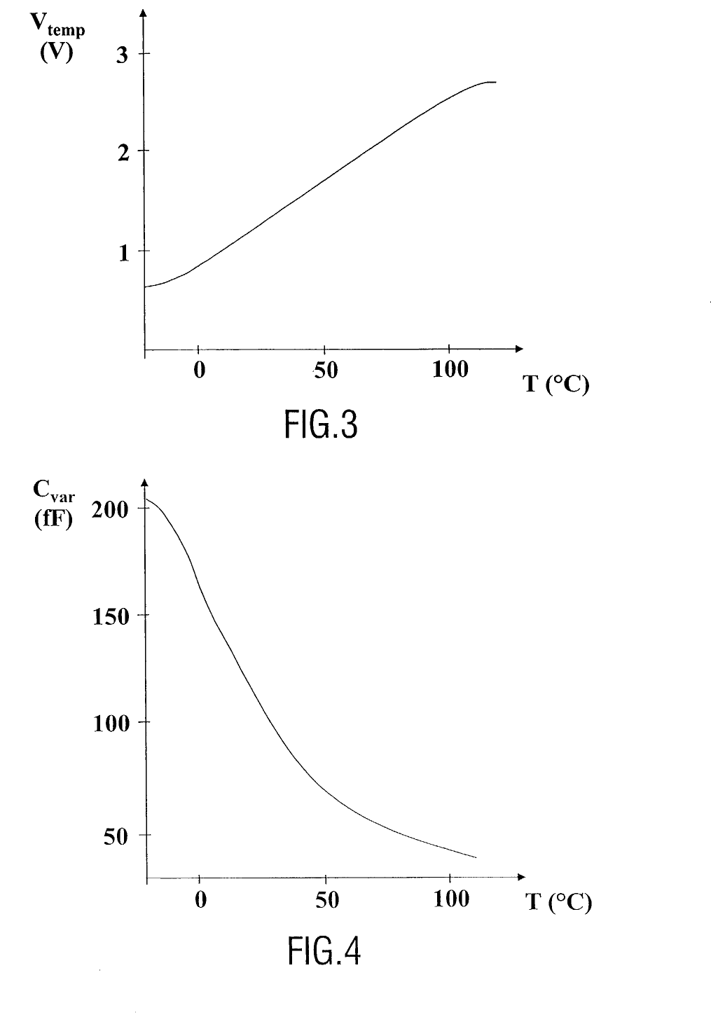

FIG. 3 shows an example of the variation of the bias signal Vₜₑₘₚ as a function of the temperature, obtained by a circuit of the type described with reference to FIG. 2. This bias signal illustrates the increasing monotonous variation of its level when the temperature rises.

FIG. 4 illustrates an example of the variation of the variable capacitance Cᵥₐᵣ as a function of the temperature when a junction is reverse-biased by the bias signal Vₜₑₘₚ described with reference to FIG. 3. The bias signal Vₜₑₘₚ increases when the temperature rises and the value of the variable capacitance Cᵥ decreases when the temperature rises.

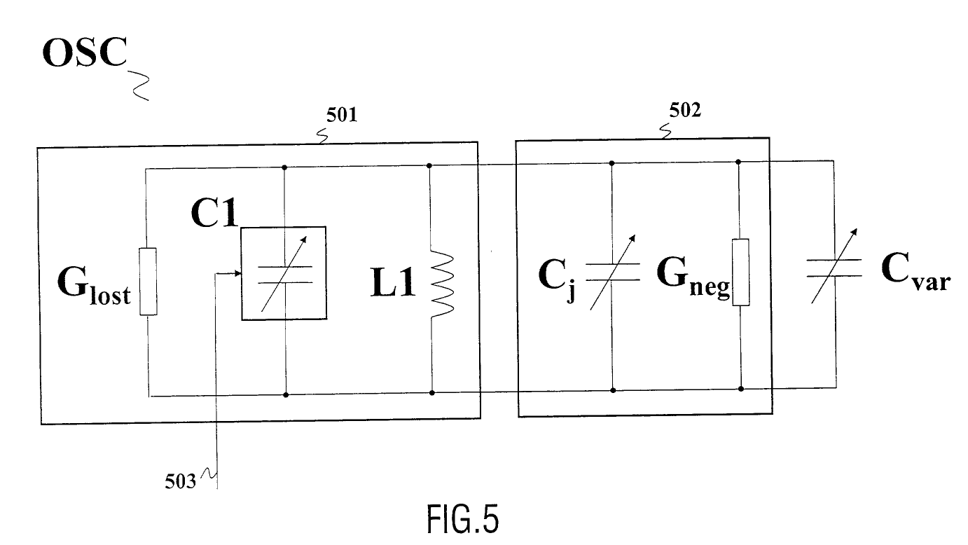

FIG. 5 is a simplified circuit of an oscillator OSC associated with a compensation device according to the invention.

The oscillator OSC is composed of a passive resonant circuit 501, an active circuit 502 and the variable capacitance Cᵥₐᵣ obtained by the previously described compensation device according to the invention. The elements 501-502 and Cᵥₐᵣ are connected in parallel.

The nominal resonance frequency of the oscillator is given by the frequency of the resonant circuit 501, particularly by the elements C1-L1. The resonant circuit 501 comprises the parallel arrangement of an inductance L1, a capacitance C1 having a variable value as a function of a control voltage 503, and a positive conductance Gₗₒₛₜ diagrammatically showing the losses of the elements C1-L1. A variation of the level of the control voltage 503 involves a variation of the capacitance C1, with which the resonance frequency of the resonant circuit 501 can be varied.

In order that the oscillations of the resonant circuit 501 are maintained, the active circuit 502 is connected in parallel with the passive resonant circuit 501. The active circuit 502 allows generation of a negative conductance G_{neg} compensating the losses caused by the conductance Gₗₒₛₜ. The active circuit comprises active elements (not shown) of the transistor type having an intrinsic capacitance which varies with the temperature. In the case considered, the cumulation of the intrinsic capacitances of the assembly of said transistors is equivalent to the parallel connection with the negative conductance G_{neg} of an intrinsic capacitance Cⱼ having a value which increases when the temperature rises.

To prevent the capacitance Cⱼ from involving a modification of the nominal resonance frequency of the resonant circuit 501, the variations of the capacitance Cⱼ are compensated by using said variable capacitance Cᵥₐᵣ in parallel with the capacitance Cⱼ. A positive variation of the capacitance Cⱼ will thus be compensated by a negative variation of the capacitance Cᵥₐᵣ. Inversely, a negative variation of the capacitance Cⱼ will be compensated by a positive variation of the capacitance Cᵥₐᵣ. As the variation of the capacitance Cᵥₐᵣ compensates the variation of the capacitance Cⱼ, it is not necessary to vary the control voltage 503 so as to maintain said nominal resonance frequency at a constant value.

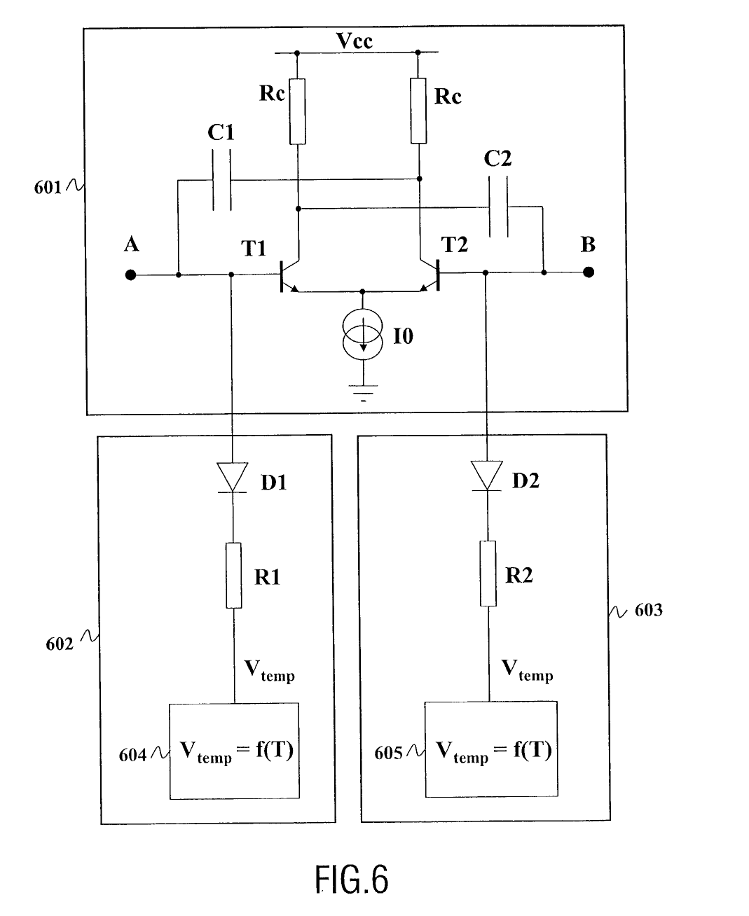

FIG. 6 is a detailed representation of a circuit 601 associated with two compensation devices 602-603 according to the invention. This circuit 601 is intended to generate a negative conductance G_{neg} between the two terminals A and B with a view to usage in an oscillator as described with reference to FIG. 5.

The circuit 601 includes a first and a second transistor T1 and T2 connected to form a differential pair. These transistors are realized in a bipolar technology in this case and have bases, collectors and emitters constituting command, transfer and reference terminals, respectively. It is of course also envisageable to substitute them for transistors of the field effect type, whose gates, drains and sources then constitute the control, transfer and reference terminals, respectively.

The transfer terminals of said transistors are connected to a power supply terminal Vcc via load resistances Rc, while the reference terminals of the first and second transistors T1 and T2 are jointly connected to ground of the circuit via a current source I0 intended to bias the differential pair. The circuit also includes a first capacitance C1 arranged between the control terminal of the transistor T1 and the transfer terminal of the transistor T2, and a second capacitance C2 arranged between the control terminal of the transistor T2 and the transfer terminal of the transistor T1. The capacitances C1 and C2 constitute a negative feedback on the control terminal of the transistors, which allows generation of said negative conductance G_{neg} between the terminals A and B.

To compensate the variation of the intrinsic capacitances of the transistors T1 and T2 and thus prevent any drift of the nominal resonance frequency when this circuit 501 is used in an oscillator, a first compensation device 602 is associated with the transistor T1 and a second compensation device 603 is associated with the transistor T2.

The compensation device 602 comprises a generator 604 for generating a bias signal Vₜₑₘₚ with which the junction D1 can be reverse-biased via the resistance R1. For example, the generator 604 is of the type as described with reference to FIG. 2. When the temperature varies, the variation of the intrinsic capacitance of the transistor T1 is thus compensated by a variation of the variable capacitance formed by the junction of the diode D1, i.e. indirectly compensated by the bias signal Vₜₑₘₚ. As the diode D1 is reverse-biased, such a compensation device does not inject any current in the circuit 601 so that the bias of the circuit 601 is not modified. The compensation devices 602 and 603 have identical structures and the elements D2-R2-605 have the same function as the elements D1-R1-604. When the temperature varies, the variation of the intrinsic capacitance of the transistor T2 is thus compensated by a variation of the variable capacitance formed by the junction of the diode D2, i.e. indirectly compensated by the bias signal Vₜₑₘₚ . The association of the intrinsic capacitance of T1 and the intrinsic capacitance of T2, equivalent to the capacitance Cⱼ described with reference to FIG. 5, is thus compensated by the two compensation devices 602-603.

With a view to reduction of costs, it is envisageable to use only a single generator for the bias signal Vₜₑₘₚ supplying the same bias signal to the junctions D1 and D2.

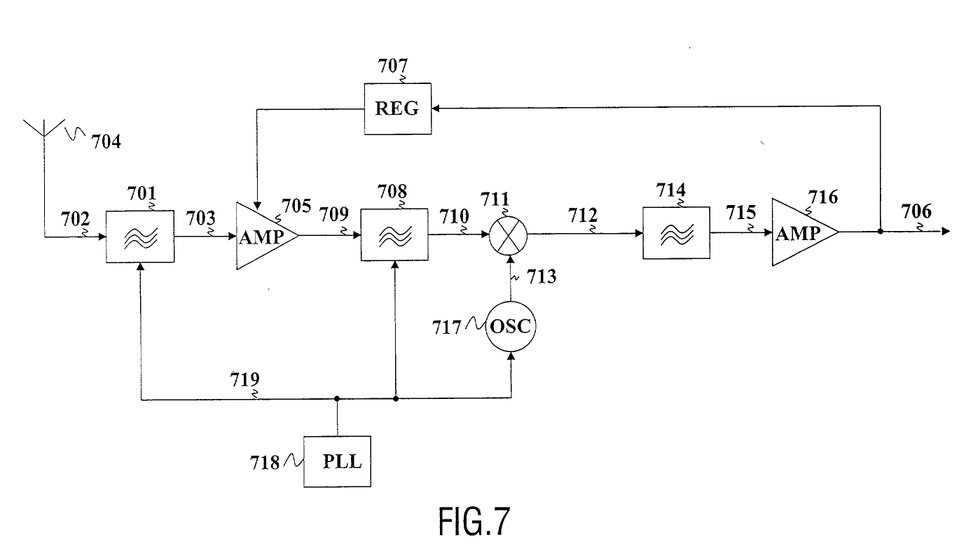

FIG. 7 shows a tuner comprising an oscillator OSC 717 as described with reference to FIG. 5 and associated with a compensation device according to the invention, as described with reference to FIG. 6. The function of the tuner is to convert a RF signal 702 into an IF output signal 706.

The tuner comprises filtering means 701 receiving the RF signal 702 and supplying a first filtered signal 703. The filtering means 701 effect, on the one hand, a level and impedance matching with the receiving means 704 (antenna, cable) and, on the other hand, a selective filtering in the spectrum of the signal 702 around the frequency spectrum of the desired channel. The filtered signal 703 is amplified by an amplifier 705 in such a way that the amplitude of the IF output signal 706 remains constant regardless of the level of the RF signal 702. To this end, regulation means 707 allowing automatic gain control of the filtered signal 703 by the amplifier 705 are provided. The filtering means 708 filter the amplified signal 709 so as to accentuate the selectivity of the desired channel for generating an output signal 710. Particularly, the filtering means 708 allow suppression of the picture frequencies in the frequency spectrum. The tuner also comprises a mixer 711 for converting the RF input signal 710 into an IF output signal 712. The mixer 711 receives the output signal 713 generated by the oscillator 717 which is controlled by a control voltage 719. The mixer 711 multiplies the input signal 710 by said output signal 713 involving a frequency shift of the signal 710. The IF signal 712 whose frequency is equal to the difference between the frequencies of the signals 713 and 710 is filtered by the filtering means 714 so as to attenuate the RF residues and generates a filtered IF signal 715. Particularly, the filtering means 714 attenuate the residual frequencies from the mixer 711, as well as the residual frequencies from channels which are adjacent to the desired channel and which have not been completely suppressed by the filtering means 701 and 708. The filtered IF signal 715 is subsequently amplified by means of the amplifier 716 so as to generate said IF output signal 706. Control means 718 of the phase-locked loop type (PLL) allow control of the central frequency of the filtering means 701 and 708, and ensure the stability of the frequency of the signal 713 by supplying a control voltage 719 of a variable level to the oscillator 717.

The use of a compensation device according to the invention is particularly advantageous because it allows compensation of the variation of the intrinsic capacitances of the transistors with which the negative conductance of the oscillator 717 can be generated, without the control voltage 719 being modified. This prevents a shift of the filtering means 701 and 708, which leads to a better linearity of operation of the tuner when the temperature varies.

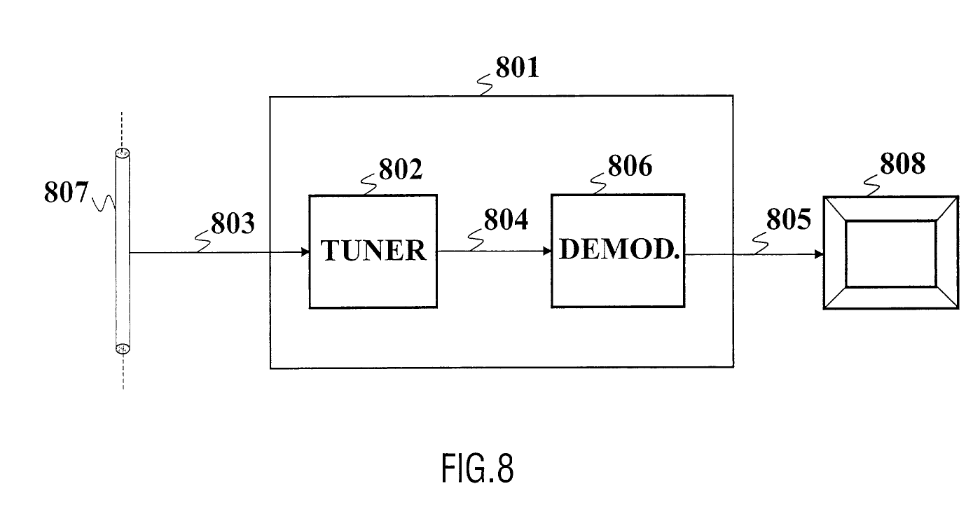

FIG. 8 shows an electronic apparatus for receiving television signals, comprising a tuner provided with a compensation device according to the invention.

This electronic apparatus is dedicated to the reception of a RF signal 803, its conversion into an IF signal 804 and the demodulation of the signal 804 for generating the demodulated output signal 805 via the demodulation means 806. In so far as the RF signal 803 may comprise channels modulated in accordance with an analog technique and channels modulated in accordance with a digital technique, the tuner 802 is of the hybrid type.

This apparatus 801 is, for example, of the set-top box type dedicated to the reception of a RF video signal 803 transmitted via a cable network 807. The IF signal 804 supplied by the tuner according to the invention is subsequently amplified and demodulated by the processing means 806 with a view to visualizing the video contents via display means 808.

In another embodiment, the display means 808 form an integral part of the apparatus 801 for constituting a television set.

The invention has been described in the case where the intrinsic junction capacitances—having a value which increases with a rise of the temperature—are added to an extrinsic capacitance forming part of an electronic assembly. As described, the variable capacitance Cᵥₐᵣ according to the invention presents a variation of the decreasing value for realizing the compensation, which compensation is possible via the generation of a bias signal Vₜₑₘₚ having an increasing value.

It is possible to envisage electronic assemblies in which the intrinsic capacitance is subtracted from an extrinsic capacitance. In this case, the variable capacitance Cᵥₐᵣ according to the invention must have a variation of an increasing value for realizing the compensation, which is possible via the generation of a bias signal Vₜₑₘₚ of a decreasing value. In other words, in this case, the capacitance Cᵥₐᵣ of a variable value must have the same sense of variation as said intrinsic capacitance so as to realize the compensation of the assembly. To this end, and without departing from the scope of the invention, those skilled in the art can use bias means for generating a bias signal having a value which decreases with a rising temperature. For example, such a bias signal may be obtained via an inverter amplifier arranged at the output of the assembly described with reference to FIG. 2, or taken from an output of a voltage divider bridge arranged between the emitter of the transistor T1 and the power supply Vcc.

The invention has been described within the scope of compensating the intrinsic capacitance of a transistor of the bipolar type. However, without departing from the scope of the invention, the invention may also be used within the scope of compensating the intrinsic capacitance of field effect transistors in so far as the latter also have intrinsic capacitances which are similar to those of the bipolar transistors.

1. An electronic apparatus comprising at least one transistor having a control terminal and an intrinsic capacitance junction with a variable value as a function of the temperature, said transistor being associated with a compensation device for compensating the effects of the variation of said intrinsic capacitance junction, characterized in that said compensation device comprises a combination of means behaving as a variable capacitance, said variable capacitance having such a variation as a function of the temperature that it compensates said effects, said variable capacitance being connected to said intrinsic capacitance.

2. An electronic apparatus as claimed in claim 1, characterized in that the combination of means comprises:
means for generating a bias signal of a variable level as a function of the temperature,
a junction which is reverse-biased by said bias signal, said reverse-biased junction being connected to said control terminal.

3. An electronic apparatus as claimed in claim 2, characterized in that the generating means comprise:
a set of junctions arranged in series for generating a current of a variable value as a function of the temperature,
a current mirror of said variable current for generating said bias signal.

4. A compensation device for compensating the effects of the variation of the variable intrinsic capacitance junction as a function of the temperature, characterized in that said compensation device comprises a combination of means behaving as a variable capacitance, said variable capacitance having such a variation as a function of the temperature that it compensates said effects, said variable capacitance being connected to said intrinsic capacitance.

5. A compensation device as claimed in claim 4, characterized in that the compensation device comprises:
means for generating a bias signal of a variable level as a function of the temperature,
a junction which is reverse-biased by said bias signal, said reverse-biased junction being connected to said control terminal.

6. A compensation device as claimed in claim 5, characterized in that the generating means comprise:
a set of junctions arranged in series for generating a current of a variable value as a function of the temperature,
a current mirror of said variable current for generating said bias signal.

7. An integrated circuit comprising at least one compensation device as claimed in claim 4.

8. A tuner for receiving an RF signal, comprising a voltage-controlled oscillator, characterized in that the tuner comprises at least one compensation device as claimed in claim 4, associated with said oscillator.

9. A television signal receiver comprising a tuner as claimed in claim 8.
